(19) United States
(12) Patent Application Publication
(10) Pub. No.: US 2004/0069208 A1
(43) Pub. Date: Apr. 15, 2004

(54) Process for crystallizing enantiomerically enriched 2-acetylthio-3-phenylpropionic acid

(76) Inventor: Franciscus Alphons Marie Lommen, Horst (NL)

Correspondence Address: Kate H Murashige, Morrison & Foerster, Suite 500, 3811 Valley Centre Drive, San Diego, CA, 92130-2332, US

(21) Appl. No.: 10/333,057

(22) PCT Filed: Jul. 12, 2001
(86) PCT No.: PCT/NL01/00534

(30) Foreign Application Priority Data
Jul. 14, 2000 (NL) 1015714

(51) Int. Cl. C30B 1/00

(52) U.S. Cl. 117/2

(57) ABSTRACT

Process for crystallizing 2-acetylthio-3-phenylpropionic acid from a solution of acetylthiophenylpropionic acid, wherein, at a temperature lower than 50° C., an antisolvent is added to form a mixture of antisolvent and acetylthiophenylpropionic acid solution; wherein seed crystals are added to the mixture before crystallisation occurs; and wherein the antisolvent is dosed over time during the occurrence of crystallisation.

Preferably, the crude reaction mixture obtained in the preparation of the acetylthiophenylpropionic acid is applied as acetylthiophenylpropionic acid-containing medium.

Preferably the seed crystals are added while the mixture is in the metastable phase range.

Free flowing acetylthiophenyl propionic acid particles are obtained. The invention also relates to such particles.

The invention relates to a process for crystallizing acetylthiophenylpropionic acid.

Acetylthiophenylpropionic acid, in particular S-acetylthiophenylpropionic acid, is a known intermediate product in the production of pharmaceuticals, for example omapatrilate.

EP-A-0747392 describes in an example that an acetylthiophenylpropionic acid is obtained as crystalline solid. In this process the acetylthiophenylpropionic acid is first recovered as dicyclohexylamine salt from the obtained reaction mixture, whereupon the salt is again hydrolyzed and subsequently the acetylthiophenylpropionic acid is obtained in solid form.

Such a process is complicated and expensive. Furthermore it has been found that in the described manner acetylthiophenylpropionic acid is obtained as a lump of caked, solidified oil which cannot be removed easily from the reactor. In order to be able to be removed the solid must be redissolved and/or remelted in for example ethyl acetate, or must be recovered through special techniques, for example flaking.

The invention provides a process wherein free-flowing acetylthiophenylpropionic acid particles are obtained.

This is achieved according to the invention when acetylthiophenylpropionic acid is made to crystallize from an acetylthiophenylpropionic acid solution at a temperature lower than 50° C., with an antisolvent being added so that a mixture of antisolvent and the acetylthiophenylpropionic acid solution is obtained and wherein seed crystals are added to the mixture before spontaneous crystallisation occurs. In this process the antisolvent is preferably dosed over time during crystallisation.

Preferably, the reaction mixture is stirred during crystallisation and dosing of the seed crystals. The optimal stirring rate depends on the reaction mixture and can readily be determined through experiment by those skilled in the art. The rate at which crystallisation takes place is dependent on the dosing time. The dosing rate of the antisolvent during crystallisation is preferably so chosen that the dosing time during crystallisation is between 2 and 20 hours, in particular between 4 and 8 hours.

It has been found that with the process according to the invention free-flowing, in particular easily filterable, acetylthiophenylpropionic acid particles can be obtained, even when the acetylthiophenylpropionic acid solution is the crude reaction mixture obtained in the preparation of the acetylthiophenylpropionic acid. The crude reaction mixture is preferably first subjected, in a known manner, to one or more extractions, for example with water with a suitable pH. The thiophenylpropionic acid may be prepared for example by reacting 2-bromine-3-phenylproprionic acid with thioacetic acid in the presence of a (organic or inorganic) base or with a salt, for example potassium salt or sodium salt of thioacetic acid in (for example) an organic solvent. Preferably, in the framework of the present invention, a solvent is applied with the lowest possible polarity, wherein the acetylthiophenylpropionic acid still dissolves well, for example an aromatic hydrocarbon, in particular toluene or xylene, an ester, for example an alkyl ester of acetic acid, in particular isopropyl acetate or ethyl acetate, or an ether, for example t-butyl-methyl ether. This leads to a minimal need for antisolvent.

Preferably the seed crystals are added to a homogeneous mixture of antisolvent and solution, that is, before an oil phase separates in the mixture. It has been found that crystals of acetylthiophenylpropionic acid can then be obtained that are pure while the byproducts remain in solution. Furthermore it has been found that any impurities present can be removed easily and rapidly by for example washing with for example solvent or antisolvent, preferably a mixture of solvent and antisolvent.

The temperature at which crystallisation is carried out usually is between 0 and 50° C., preferably between 10 and 40° C. The optimal temperature for crystallisation according to the invention depends in part on the ratio of the quantity of solvent to that of antisolvent. When at the start of crystallisation the ratio of solvent in the medium to antisolvent is higher, it is preferable to choose a lower temperature, while with lower ratios of solvent in the medium to antisolvent, it is preferable to choose a higher temperature.

The concentration of acetylthiophenylpropionic acid in the medium is preferably chosen to be as high as possible, it being ensured that no premature crystallisation or oil formation occurs. Under otherwise equal conditions, for example temperature, preferably a higher solvent-to-antisolvent ratio is chosen when a higher concentration is applied.

For the purposes of the present invention, the metastable range in the phase diagram is understood to be the range in which supersaturation occurs but in which no crystallisation or oil formation occurs without addition of seed crystals. Seed crystals preferable are added in the metastable range in the phase diagram.

Crystals of acetylthiophenylpropionic acid may be applied in any form as seed crystals. Preferably as pure seed crystals as possible, for example with a chemical purity >98%, preferably >99%, are added. When crystals of one of the enantiomers are desired, preferably seed crystals of the desired enantiomer (S or R) of acetylthiophenylpropionic acid are applied with an enantiomeric excess (ee) of >99%, in particular >99.5%.

The quantity of seed crystals to be applied in practice is for example between 0.01 and 10 wt %, preferably between 0.1 and 10 wt % relative to the quantity of acetylthiophenylpropionic acid.

As antisolvent in the crystallisation use may be made of for example solvents with a low polarity, preferably with a polarity, expressed as the dielectric constant, of less than 2.2, in particular less than 2.0. Preferably an as apolar as possible solvent is applied as antisolvent, for example an alkane, in particular heptane or mixtures of alkanes, for instance petroleum ethers.

With the process according to the invention crystalline (orthorhombic) free-flowing acetylthiophenylpropionic acid particles are obtained in the form of needles, which can be isolated from the mixture by simple techniques, for example filtration (by centrifuge). Surprisingly, it has been found that the impurities are easy to remove from these particles, for example by washing with for example solvent and/or antisolvent, preferably With a mixture of solvent and antisolvent.

With the process according to the invention acetylthiophenylpropionic acid particles with an average length/diameter ratio of between 3 and 15, in particular between 4 and 10 can be obtained. The length of the particles is characterized in that 90 wt % of the particles has a length of between 0.05 and 2 mm, in particular between 0.2 and 1 mm. The acetylthiophenyl propionic acid preferably has an ee>95%, in particular >99%, more in particular >99%.

The invention is elucidated with reference to the following example, without being limited thereby.

### EXAMPLE

95 ml of water was added to the reaction mixture obtained in the preparation of S-acetylthiophenyl propionic acid starting from 45.0 grams of D-Phenylalanine and the mixture was heated to 20° C.

The reaction mixture was brought to pH=3.4 with the aid of HCl 32%. Stirring was stopped and the aqueous phase was separated.

The organic phase was then washed with 95 ml of sodium thiosulfate solution (5%) in water.

95 ml of water was added to the organic phases and the mixture was brought to pH=0.75 with the aid of HCl 32%. Subsequently, the aqueous phase was separated and the toluene phase was extracted once again with 95 ml of water.

The yield of S-acetylthiophenyl propionic acid in the toluene solution relative to D-Phenylalanine amounted to 82.5%, determined through HPLC analysis.

Using a Dean-Stark apparatus, the water was distilled off azeotropically at 60° C. and a pressure of 100 mbar until the toluene phase was anhydrous.

The toluene phase was subsequently evaporated to a residual volume of 135 ml and was filtered through a paper filter at a temperature of approximately 40° C. The filter was rinsed with 10 ml of toluene. The filtered toluene solution was reintroduced in the reactor, whereupon stirring was started.

A total 360 ml of petroleum ether 80-110 was dosed to the filtered toluene solution. First 108 ml was dosed in half an hour, with the temperature being maintained above 33° C. Next, the solution was cooled carefully to 32.0° C. The remaining quantity of petroleum ether 80-110 (252 ml) was dosed in 6 hours with the temperature being kept constant between 31.0 and 33.0° C. After adding 144 ml out of the total quantity of petroleum ether 80-110, 0.20 gram of S-acetylthiophenyl propionic acid seeds were added. After adding 180 ml of petroleum ether 80-110 again 0.20 gram of S-acetylthiophenyl propionic acid seeds were added. After 216 ml of petroleum ether 80-110, 0.20 gram S-acetylthiophenyl propionic acid seeds were added for the third time.

Slow crystallisation occurred during dosing upward from 144 ml of petroleum ether.

The reaction mixture was cooled to 0° C. in 11 hours: From 32 to 25° C. in 5 hours followed by cooling to 15° C. in 3 hours followed by cooling to 0° C. in 3 hours. At 0° C., stirring took place for 2 hours.

With the aid of a Buchner funnel the product was filtered and washed with 2 portions of a 40 ml toluene petroleum ether 80-110 mixture (20-80 V/V) of 0° C.

The S-acetylthiophenyl propionic acid crystals were dried for 4 hours at 40° C. and a pressure of <20 mbar.

Yield: 41.5 grams of S-acetylthiophenyl propionic acid. Relative to D-phenylalanine this is 68%.

Microscopic examination indicated that the particle size ranged from about 0.2 to about 1 mm. The average length/diameter ratio was about 7.

Chemical data (S)-2-acetylthio-3-phenylpropanoic acid:

Melting point: 65° C.

¹H-NMR (300 MHz)

δ (ppm): 2.3 (s, 3H, CH₃); 2.9 (dd, 1H, CHH); 3.2 (dd, 1H, CHH); 4.2 (t, 1H, CH); 7.2-7.4 (m, 5H, Phenyl)

IR (neat)

ν (cm⁻¹): 617 (C—S stretch); 679 (C—S—C stretch); 700 (aromatic ring vibration); 744 (aromatic ring vibration); 1460-1350 (C—H bending); 1497 (C—H bending); 1600 (C═C in ring); 1667 (C═O stretch); 1702 (C═O around); 2925 (C—H stretch); 2949 (C—H stretch); 2700-3200 (broad, OH stretch).

Crystal data:

C₁₁H₁₂O₃S, orthorhombic, space group P2₁2₁2₁, a=5.4089(9), b=8.7274(6), c=24.6436(19) Å, V=1163.3(2) Å³, Z=4.

1. Process for crystallizing 2-acetylthio-3-phenylpropionic acid from a solution of acetylthiophenylpropionic acid, wherein, at a temperature lower than 50° C., an antisolvent is added to form a mixture of antisolvent and acetylthiophenylpropionic acid solution, wherein seed crystals are added to the mixture before spontaneous crystallisation occurs, and wherein the antisolvent is dosed over time during the occurrence of crystallisation.

2. Process according to claim 1, wherein the crude reaction mixture obtained in the preparation of the acetylthiophenylpropionic acid is applied as acetylthiophenylpropionic acid-containing medium.

3. Process according to claim 2 wherein the acetylthiophenylpropionic acid has been obtained by reacting 2-bromine-3-phenylpropionic acid with thioacetic acid or a salt thereof in a polar organic solvent.

4. Process according to any one of claims 1-3, wherein the seed crystals are added while the mixture is in the metastable phase range.

5. Process according to any one of claims 1-4, wherein the metering time of the antisolvent during crystallisation is between 2 and 20 hours.

6. Process according to claim 5, wherein the metering time is between 4 and 8 hours.

7. Process according to any one of claims 1-6, wherein an antisolvent with a dielectric constant of less than 2.2 is applied.

8. Process according to claim 7, wherein an antisolvent with a dielectric constant of less than than 2.0 is applied.

9. Process according to any one of claims 1-8, wherein the obtained acetylthiophenylpropionic acid is subsequently converted into a pharmaceutical, in particular omapatrilate.

10. Crystalline acetylthiophenyl propionic acid particles.

11. Acetylthiophenyl propionic acid particles with an average length/diameter ratio between 3 and 15, preferably between 4 and 10.

12. Acetylthiophenyl propionic acid particles according to claim 10 with a particle length between 0.05 and 2 mm, preferably between 0.2 and 1 mm.
